(19) United States
(12) Patent Application Publication
(10) Pub. No.: US 2015/0043288 A1
(43) Pub. Date: Feb. 12, 2015

(54) SEMICONDUCTOR MEMORY DEVICE HAVING FUSE CELL ARRAY

(71) Applicant: SK hynix Inc., Gyeonggi-do (KR)

(72) Inventor: Kwi-Dong KIM, Gyeonggi-do (KR)

(73) Assignee: SK hynix Inc., Gyeonggi-do (KR)

(21) Appl. No.: 14/107,254

(22) Filed: Dec. 16, 2013

(30) Foreign Application Priority Data
Aug. 9, 2013 (KR) 10-2013-0094596

(51) Int. Cl. G11C 17/14

(52) U.S. Cl. CPC G11C 17/14
USPC 365/189.05; 365/200

(57) ABSTRACT

A semiconductor memory device includes a plurality of fuses arranged in an array suitable for storing N number of repair column addresses, each having M bits and corresponding to a repair target memory cell, a fuse selection unit suitable for selecting M fuses corresponding to one of the N number of repair column addresses in the plurality of fuses in response to an active command and an external row address, which are applied from outside, and outputting one of the N number of repair column addresses corresponding to the selected M fuses, and a repair determination unit suitable for determining whether or not a column address applied from the outside corresponds to the repair target memory cell based on the repair column address outputted by the fuse selection unit.

### CROSS-REFERENCE TO RELATED APPLICATIONS

The present application claims priority of Korean Patent Application No. 10-2013-0094596, filed on Aug. 9, 2013, which is incorporated herein by reference in its entirety.

### BACKGROUND

1. Field

Exemplary embodiments of the present invention relate to a semiconductor memory device, and more particularly, to a semiconductor memory device including a fuse cell array for a repair operation.

2. Description of the Related Art

In general, a semiconductor memory device including a double data rate (DDR) synchronous dynamic random access memory (SDRAM) has a large number of memory cells provided therein. With the development of process technology, a number of memory cells have gradually increased as the integration degree of the semiconductor memory device has gradually increased. With the increase in operation speed of a system including semiconductor memory devices and the development of technology related to semiconductor integrated circuits, the semiconductor memory device has been required to output or store data at higher speed. Recently, a demand for a semiconductor memory device capable of reading and writing a larger amount of data with reduced power consumption and higher speed has continuously increased. Furthermore, as the semiconductor memory device is required to have a higher capacity, numbers of signal lines and unit cells included in the semiconductor chip have rapidly increased.

Therefore, the design and fabrication process of the semiconductor memory device have become more complex. Furthermore, as components included in the semiconductor memory device become reduced in size, a defect becomes highly likely to occur. As a number of defects occurring between various signal lines or between a signal line and a unit cell increase, a defect rate of the entire semiconductor memory device increases.

In general, each of a plurality of banks included in the semiconductor memory device includes a cell mat having a plurality of unit cells, a column control region for controlling a column region, and a redundancy circuit for replacing a defective unit cell of the semiconductor memory device.

The redundancy circuit includes a column redundancy circuit disposed in the column control region of the bank for repairing a column address of the defective unit cell. The defective memory cell is replaced with a redundancy memory cell. In the specification of the present application, the defective memory cell, which is to be replaced with the redundancy memory cell, is referred to as a ‘repair target memory cell’.

The semiconductor memory device includes a fuse circuit for programming an address corresponding to the repair target memory cell. The programming of the address refers to a series of operations for storing the address corresponding to the repair target memory cell in the fuse circuit. An electrical cutting and a laser cutting are known methods for programming a fuse provided in the fuse circuit. According to the electrical cutting, the fuse to be cut for the program of the address, or cutting-target fuse, is to be melted and cut by application of an over-current to the cutting-target fuse. According to the laser cutting, the cutting-target fuse is to be cut by blow to the cutting-target fuse through laser beam.

Replacement of the repair target memory cell with the redundancy memory cell is referred to as a repair operation. More specifically, a failed address which indicates a location of the repair target memory cell is detected using a semiconductor test device. The failed address is stored by programming the fuse circuit. After the failed address is stored in the fuse circuit, if an input address indicates the failed memory cell, it is determined that the failed address stored in the redundancy circuit is same as the input address. Thus, the repair operation is performed as described below. An access to the failed memory cell is cut off by inactivating a failed path, which is an access to the target memory cell, and an access to the redundancy memory cell is admitted by activating a redundancy path in response to an operation of a row decoder or a column decoder.

Currently, the integration degree of the semiconductor memory device is further increased and attempts to reduce the entire area are continuously made to improve productivity. The smaller the area of the semiconductor memory device, the larger a number of the semiconductor memory devices, which may be fabricated in one wafer. As the number of the semiconductor memory device fabricated in one wafer increases, the fabrication cost decreases. Furthermore, with increase of storage capacity of the semiconductor memory device, the number of unit cells included in the semiconductor memory device has increased. Thus, the size of the redundancy circuit for repairing the defective unit cell inevitably increases, which makes it difficult to reduce the entire area of the semiconductor memory device. Therefore, due to such problems, a fuse cell array is currently used. The fuse cell array has a smaller size than the redundancy circuit having an existing metal fuse and may be implemented through an existing CMOS process.

### SUMMARY

Various exemplary embodiments are directed to a semiconductor memory device including a fuse cell array for a repair operation.

In an exemplary embodiment, a semiconductor memory device may include a plurality of fuses arranged in an array suitable for storing N number of repair column addresses, each having M bits and corresponding to a repair target memory cell, a fuse selection unit suitable for selecting M fuses corresponding to one of the N number of repair column addresses in the plurality of fuses in response to an active command and an external row address that are applied from outside, and outputting one of the N number of repair column addresses corresponding to the selected M fuses, and a repair determination unit suitable for determining whether or not a column address applied from the outside corresponds to the repair target memory cell based on the repair column address outputted by the fuse selection unit.

In an exemplary embodiment, a semiconductor memory device may include a memory cell array including a plurality of cell arrays, a row decoder suitable for decoding an external row address inputted from outside and outputting a row address, which is an information of a memory cell mat including an activated word line, a fuse cell array suitable for storing one or more repair column addresses and outputting one or more of the repair column addresses in response to the row address, a repair determination unit suitable for comparing a column address inputted from the outside with the repair column address outputted by the fuse cell array and outputting a repair determination signal based on the comparison result and a column decoder suitable for decoding the column address and selecting a column of the memory cell array in response to the repair determination signal.

In an exemplary embodiment, there is provided an operating method of a semiconductor memory device, which includes a plurality of fuses arranged in an array for storing N number of repair column addresses, each having M bits and corresponding to a repair target memory cell. The operating method may include decoding an external row address applied from outside in response to an active command and outputting a row address, which is an information of a memory cell mat corresponding to one of memory cell arrays included in the semiconductor memory device, selectively activating a plurality of word lines arranged in each of the memory cell arrays in response to the row address, selecting M fuses corresponding to one of the N number of repair column addresses in the plurality of fuses in response to the active command and the row address during an operation period of the activating of the plurality of word lines, and outputting one of the N number of repair column addresses corresponding to the selected M fuses.

### BRIEF DESCRIPTION OF THE DRAWINGS

FIG. 1 is a block diagram illustrating a semiconductor memory device in accordance with an exemplary embodiment of the present invention.

FIG. 2 is a detailed block diagram illustrating a row decoder of the semiconductor memory device shown in FIG. 1.

FIG. 3 is a circuit diagram illustrating a fuse cell array of the semiconductor memory device shown in FIG. 1.

FIG. 4 is a timing diagram illustrating a fuse cell array of the semiconductor memory device in accordance with an embodiment of the present invention.

### DETAILED DESCRIPTION

Various embodiments will be described below in more detail with reference to the accompanying drawings. The present invention may, however, be embodied in different forms and should not be construed as limited to the embodiments set forth herein. Rather, these embodiments are provided so that this disclosure will be thorough and complete and will fully convey the scope of the present invention to those skilled in the art. Throughout the disclosure, reference numerals correspond directly to the like numbered parts in the various figures and embodiments of the present invention. Furthermore, “connected/coupled” refers to one component not only directly coupling another component but also indirectly coupling another component through an intermediate component. In addition, a singular form may include a plural form as long as it is not specifically mentioned in a sentence.

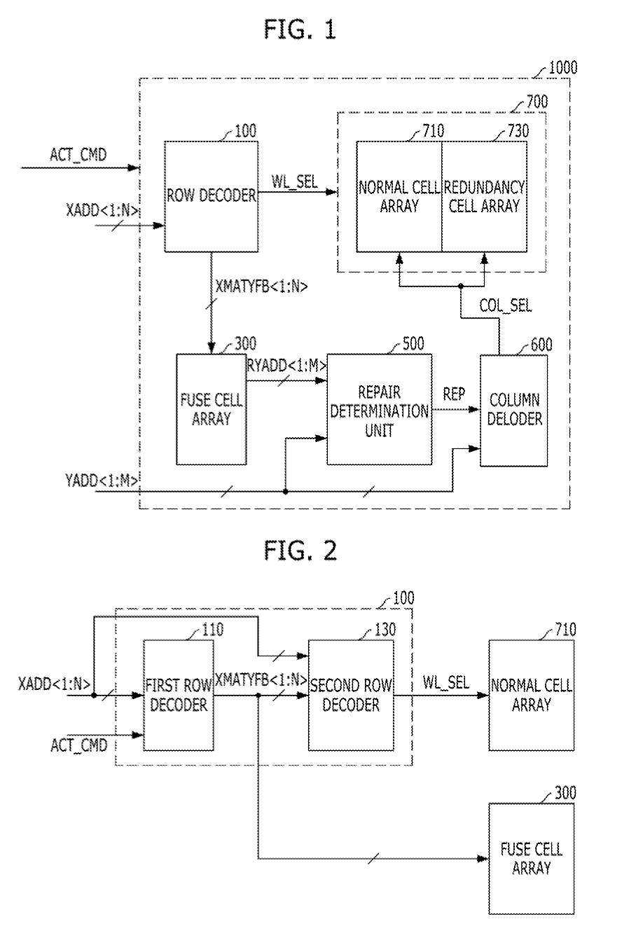

FIG. 1 is a block diagram illustrating a semiconductor memory device in accordance with an exemplary embodiment of the present invention.

Referring to FIG. 1, the semiconductor memory device 1000 may include a row decoder 100, a fuse cell array 300, a repair determination unit 500, a column decoder 600, and a memory cell array 700. The memory cell array 700 may include a normal cell array 710 and a redundancy cell array 730.

The row decoder 100 may receive and decode an active command ACT_CMD and a row address XADD<1:N> inputted from outside, output a word line select signal WL_SEL for selecting and activating one of a plurality of word lines and output a row address XMATYFB<1:N>, which is an information of a memory cell mat including the activated word line. Here, N is a positive integer.

The fuse cell array 300 may store a repair column address RYADD<1:M> corresponding to the repair target memory cell and output the repair column address RYADD<1:M> in response to the row address XMATYFB<1:N> outputted from the row decoder 100. Here, M is a positive integer.

The repair determination unit 500 may receive a column address YADD<1:M> inputted from the outside when a read command RD_CMD (not illustrated) for a read operation is applied to the semiconductor memory device 1000, compare the column address YADD<1:M> with the repair column address RYADD<1:M> and output a repair determination signal REP for controlling the repair operation of the memory cell array 700.

The column decoder 600 may decode the column address YADD<1:M> and the read command RD_CMD in response to the repair determination signal REP outputted from the repair determination unit 500 and output a column select signal COL_SEL for selecting a column of the memory cell array 700.

When the column address YADD<1:M> is not identical to the repair column address RYADD<1:M>, which means that the column address YADD<1:M> is not the failed address, the column decoder 600 may output the column select signal COL_SEL for selecting a normal column address of the normal cell array 710 according to the column address YADD<1:M>. On the contrary, when the input column address YADD<1:M> is identical to the repair column address RYADD<1:M>, which means that the column address YADD<1:M> is the failed address, the column decoder 600 may output the column select signal COL_SEL for selecting a redundancy column address of the redundancy cell array 730 to perform the repair operation.

FIG. 2 is a detailed block diagram illustrating the row decoder 100 of the semiconductor memory device 1000 shown in FIG. 1.

Referring to FIG. 2, the row decoder 100 may include a first row decoder 110 and a second row decoder 130.

The first row decoder 110 may decode part of the row address XADD<1:N> applied from the outside and output the row address XMATYFB<1:N>, which is an information of a plurality of memory cell mats corresponding to a plurality of memory cells, respectively, to the fuse cell array 300. For example, the first row decoder 110 may decode the most significant bit (MSB) of the input row address XADD<1:N> to output the row address XMATYFB<1:N>.

The second row decoder 130 may decode the row address XMATYFB<1:N> and the rest of the row address XADD<1:N>, which is not decoded by the first row decoder 110, and transfer the word line select signal WL_SEL for selectively activating a plurality of word lines WL disposed in each of the memory cell mats, to the normal cell array 710.

According to the embodiment of the present invention, the second row decoder 130 and the fuse cell array 300 may receive the row address XMATYFB<1:N> so that the fuse cell array 300 operates and output the repair column address RYADD<1:M> during a row decoding operation period of the second row decoder 130. Thus, according to the embodiment of the present invention, during a row decoding operation period of the second row decoder 130, the fuse cell array 300 may output the repair column address RYADD<1:M> based on the row address XMATYFB<1:N> sent from the first row decoder 110. Then, when the read command RD_CMD is applied to perform a read operation for the memory, the input column address YADD<1:M> and the repair column address RYADD<1:M> may be compared by the repair determination unit 500 to determine whether the column address YADD<1:M> is the failed address or not. Then, the repair operation of the memory cell array 700 may be controlled according to the determination result.

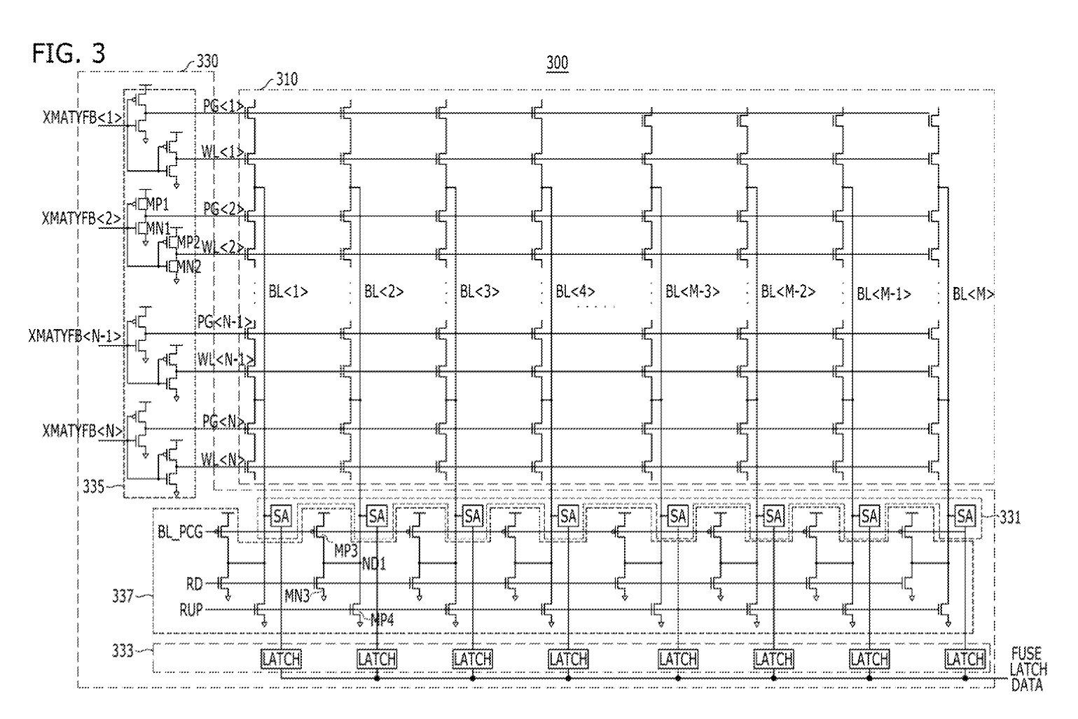

FIG. 3 is a circuit diagram illustrating the fuse cell array 300 of the semiconductor memory device 1000 shown in FIG. 1.

Referring to FIG. 3, the fuse cell array 300 may include a fuse unit 310 and a fuse selection unit 330. The fuse unit 310 may include a plurality of fuses arranged in an M*N array to store programmed N sets of M-bit repair column addresses RYADD<1:M>. The fuse selection unit 330 may select the repair column address RYADD<1:M> stored in the fuse unit 310.

The fuse cell array 300 may serve to store programmed N address sets of the repair column addresses RYADD<1:M>, each of which is an M-bit address. That is, the fuse cell array 300 may include the fuse unit 310 having M*N fuses arranged therein.

The fuse unit 310 has an array shape of a matrix in which a plurality of pairs of word lines WL<1:N> and program lines PG<1:N each pair corresponding to each bit of the row address XMATYFB<1:N>, and a plurality of bit lines BL<1:M> are arranged. Furthermore, the fuses of the fuse unit 310 may be arranged at the respective intersections between the plurality of pairs of the word lines WL<1:N> and the program lines PG<1:N>, and the plurality of bit lines BL<1:M>. In the exemplary embodiment, each of the fuses may be implemented with a transistor having a gate coupled to corresponding one in each pair of the word lines WL<1:N> and the program lines PG<1:N>.

The fuse selection unit 330 may select M fuses among the M*N fuses in response to the row address XMATYFB<1:N> and output the repair column address RYADD<1:M> stored in the selected M fuses.

The fuse selection unit 330 may include a data sensing section 331, a data latch section 333, an input driving section 335, and an operation control section 337.

The input driving section 335 may have a plurality of elements each corresponding to each of the plurality of pairs of the word lines WL<1:N> and program lines PG<1:N>. Each of the data sensing section 331, the data latch section 333, and the operation control section 337 may have a plurality of elements each corresponding to each of the plurality of bit lines BL<1:M>. Hereafter, a second program line PG<2>, a second word line WL<2>, and a second bit line BL<2> will be taken as an example, for clear description.

The input driving section 335 may receive the row address XMATYFB<1:N> and drive a corresponding one of the N pairs of the plurality of word lines WL<1:N> and program lines PG<1:N>.

The input driving section 335 may include a first PMOS transistor MP1 and a first NMOS transistor MN1, which are connected in series between a power supply voltage VDD and a ground voltage VSS and have a gate receiving the second row address XMATYFB<2>. The input driving section 335 may also include a second PMOS transistor MP2 and a second NMOS transistor MN2, which are connected in series between the power supply voltage VDD and the ground voltage VSS and have a gate receiving the second row address XMATYFB<2>. The second program line PG<2> may be connected to a common drain of the first PMOS transistor MP1 and the first NMOS transistor MN1, and the second word line WL<2> may be connected to a common drain of the second PMOS transistor MP2 and the second NMOS transistor MN2. Furthermore, the pair of the second program line PG<2> and the second word line WL<2> may correspond to a second bit of the row address XMATYFB<1:N> or XMATYFB<2> and may be connected to gates of the transistors within the fuse unit 310.

The operation control section 337 includes the third PMOS transistor MP3, the third NMOS transistor MN3 and the fourth NMOS transistor MN4, which may correspond to each of the plurality of bit lines BL<1:M>. The third PMOS transistor MP3 has a source-drain path between the power supply voltage VDD and the common drain ND1 and a gate receiving a precharge signal BL_PCG for a precharge operation of corresponding one of the bit lines BL<1:M>, for example, a second bit line BL<2>. The third NMOS transistor MN3 has a source-drain path between the power supply voltage VSS and the common drain ND1 and a gate receiving a read signal RD. The fourth NMOS transistor MN4 has a source-drain path between the power supply voltage VSS and the common drain ND1 and a gate receiving a rupture signal RUP. The second bit line BL<2> may be connected to the common drain ND1 of the third PMOS transistor MP3 and the third and fourth NMOS transistors MN3 and MN4.

The read signal RD may be a signal for reading data of the redundancy cell array 730 in the repair operation through the repair column address RYADD<1:M> stored in the fuse cell array 300, instead of reading data of the normal cell array 710 through the column address YADD<1:M> sent from the outside.

The data sensing section 331 may sense data stored in the selected M fuses in response to the row address XMATYFB<1:N> and the data latch section 333 may latch the sensed data. As illustrated in FIG. 3, the plurality of bit lines BL<1:M> are connected to the data sensing section 331 for sensing the data stored in the selected M fuses of the fuse unit 310 in response to the row address XMATYFB<1:N>. As described above, the row address XMATYFB<1:N> is a cell mat information obtained by decoding the row address XADD<1:N> applied from the outside and corresponding to a plurality of memory cells. That is, when the active command ACT_CMD is applied to perform an active operation, the fuse selection unit 330 may sense data of the M fuses activated in response to the row address XMATYFB<1:N> and output the sensed data.

The data sensing section 331 may be connected to the common drain ND1 of the third PMOS transistor MP3 and the third and fourth NMOS transistors MN3 and MN4 and may sense and store the data loaded on the common drain ND1. Furthermore, the data sensing section 331 may be connected to the data latch section 333 to latch the sensed data. The data latched by the data latch section 333 may be the repair column address RYADD<1:M>.

An operation of the semiconductor memory device in accordance with an exemplary embodiment of the present invention will be described.

The fuse cell array 300 may precharge the plurality of bit lines BL<1:M> in response to the precharge signal BL_PCG before a rupture or active mode. The precharge signal BL_PCG having a low level may turn on the third PMOS transistor MP3, and the row address XMATYFB<1:N> having a high level may turn off the fuses of the fuse unit 310, thereby precharging the bit lines BL<1:M> to a deactivated level, that is, high level.

Then, the operation for rupturing the fuses of the fuse unit 310 based on a specific row address, for example, XMATYFB<2> corresponding to the repair target memory cell may be performed. The rupture signal RUP may be provided and the specific row address, for example, XMATYFB<2> corresponding to the repair target memory cell may be activated to a low level to program the repair column addresses RYADD<1:M> through the rupture. Thus, the first and second PMOS transistors MP1 and MP2 each having the gate receiving the row address XMATYFB<2> may be turned on, and the program line PG<2> and the word line WL<2> may become a high level. That is, the M fuses of the fuse unit 310, which correspond to the program line PG<2> and the word line WL<2> and indicate the repair column address RYADD<1:M> corresponding to the repair target memory cell, may become ready for rupture. In this state, when the rupture signal RUP becomes to have a high level, the fourth NMOS transistor MN4 may be turned on and the ground voltage VSS may be applied to second terminals, that is, sources of the fuses in the fuse unit 310. The power supply voltage VDD may be applied to the first terminals, i.e. the gates of the fuses in the fuse unit 310 and the ground voltage VSS may be applied to the second terminals, i.e. the sources of the M fuses. Then, the fuses of the fuse unit 310 indicating the repair column addresses RYADD<1:M> corresponding to the repair target memory cell are ruptured through electrical stress.

Then, the active command ACT_CMD may be applied to enter the active mode in which the memory operates. When the read signal RD is activated to a high level, the third NMOS transistor MN3 may be turned on. Thus, a current path passing through the second PMOS transistor MP2, the second bit line BL<2> and the third NMOS transistor MN3 between the power supply voltage VDD and the ground voltage VSS may be formed. Through the current path, a constant voltage may be applied to the common drain ND1 connected to the data sensing section 331 through voltage division. Then, the voltage of the common drain ND1 may be sensed by the data sensing section 331 to determine whether the M fuses, which correspond to the program line PG<2> and the word line WL<2> for example, are ruptured or not. The sensed fuse data may be latched by the data latch section 333, and the latched data may be outputted as the repair column address RYADD<1:M> to the repair determination unit 500.

As described above, the second row decoder 130 and the fuse cell array 300 may receive the row address XMATYFB<1:N> so that the fuse cell array 300 operates and output the repair column address RYADD<1:M> during the row decoding operation period of the second row decoder 130. In accordance with the exemplary embodiment of the present invention, since the fuse selection unit 330 of the fuse cell array 300 operates in response to the row address XMATYFB<1:N> during the row decoding operation period of the second row decoder 130, an existing register required for an existing repair circuit to read and store the fuse data prior to the row decoding operation period of the second row decoder 130 may not be required.

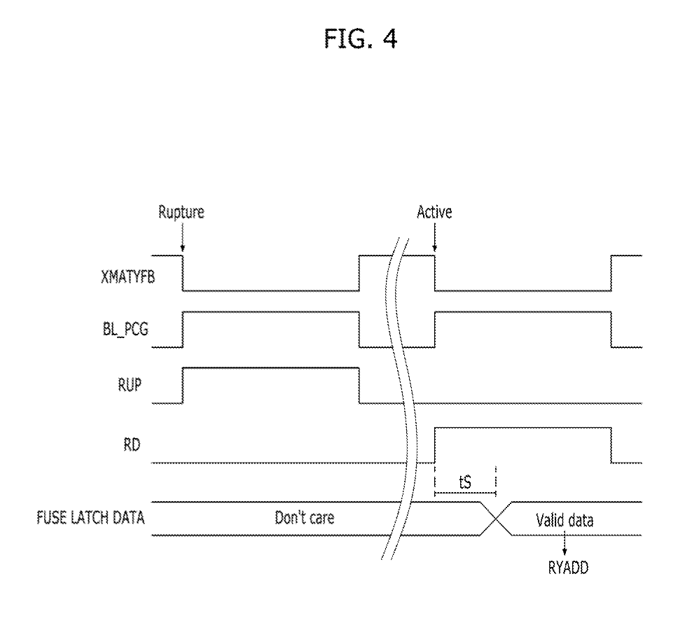

FIG. 4 is a timing diagram illustrating the fuse cell array of the semiconductor memory device 1000 shown in FIG. 1.

Referring to FIG. 4, when the rupture signal RUP is activated to a high level for the rupture operation, corresponding M fuses may be ruptured according to the specific row address, for example, XMATYFB<2>, corresponding to the repair target memory cell. The bit line precharge signal BL_PCG may be deactivated to a high level. The bit line precharge signal BL_PCG may be activated to a low level for precharging the plurality of bit lines BL<1:M>. During the active mode in which the memory operates, the read signal RD may be activated to a high level and data of the M fuses may be sensed in response to the row address XMATYFB<1:N> during a sensing time tS shown in FIG. 4. The sensed fuse data may be latched by the data latch section 333, and the latch data may be outputted as the repair column address RYADD<1:M>.

The semiconductor memory device 1000 may use the outputted fuse data after the sensing time tS is guaranteed. The sensing time tS may correspond to the row decoding operation period of the second row decoder 130 during which the word line select signal WL_SEL for selectively activating the plurality of word lines in response to the external row address XADD<1:N> is decoded by the second row decoder 130. During the sensing time tS or the row decoding operation period of the second row decoder 130, the fuse cell array 300 may sense the data of the M fuses in response to the row address XMATYFB<1:N> and the sensed data may be outputted as the repair column address RYADD<1:M>. The repair column address RYADD<1:M> may be compared with the column address YADD<1:M> sent from the outside in response to the read command RD_CMD to perform the repair operation.

In accordance with the embodiment of the present invention, the semiconductor memory device 1000 may latch data of the fuse cell array 300 whenever the active command is applied and then performs the repair operation based on the latched data that may be the repair column address RYADD<1:M>. Thus, a storage device such as the existing register required for the existing repair circuit to read and store the programmed data of the fuse cell array prior to the row decoding operation period of the second row decoder 130 may not need to be included in the repair circuit. Therefore, it is possible to reduce the area of the repair circuit and to reduce the repair operation time required for using the repair column address of the fuse cell array as a valid data.

Although various embodiments have been described for illustrative purposes, it will be apparent to those skilled in the art that various changes and modifications may be made without departing from the spirit and scope of the invention as defined in the following claims.

What is claimed is:

1. A semiconductor memory device comprising:
a plurality of fuses arranged in an array suitable for storing N number of repair column addresses, each having M bits and corresponding to a repair target memory cell;
a fuse selection unit suitable for selecting M fuses corresponding to one of the N number of repair column addresses in the plurality of fuses in response to an active command and an external row address, which are applied from outside, and outputting one of the N number of repair column addresses corresponding to the selected M fuses; and
a repair determination unit suitable for determining whether or not a column address applied from the outside corresponds to the repair target memory cell based on the repair column address outputted by the fuse, selection unit.

2. The semiconductor memory device of claim 1, further comprising:
a first row decoder suitable for decoding the external row address and outputting a row address, which is an information of a memory cell mat corresponding to one of memory cell arrays included in the semiconductor memory device; and
a second row decoder suitable for outputting a word line select signal for selectively activating a plurality of word lines arranged in each of the memory cell arrays in response to the row address,
wherein the fuse selection unit outputs the repair column address during an operation period of the second row decoder.

3. The semiconductor memory device of claim 1, wherein the fuse selection unit comprises:
a data sensing section suitable for sensing data stored in the selected M fuses; and
a data latch section suitable for latching the data sensed by the data sensing section.

4. The semiconductor memory device of claim 1, further comprising:
a memory cell array comprising a normal cell array and a redundancy cell array; and
a column decoder suitable for decoding the column address and selecting one column address between the normal cell array and the redundancy cell array in response to a determination result of the repair determination unit.

5. The semiconductor memory device of claim 4, wherein the repair determination unit and the column decoder are positioned in a column control region.

6. A semiconductor memory device comprising:
a memory cell array including a plurality of cell arrays;
a row decoder suitable for decoding an external row address inputted from outside, and outputting a row address, which is an information of a memory cell mat including an activated word line;
a fuse cell array suitable for storing one or more repair column addresses and outputting one or more of the repair column addresses in response to the row address;
a repair determination unit suitable for comparing a column address inputted from the outside with the repair column address outputted by the fuse cell array and outputting a repair determination signal based on the comparison result; and
a column decoder suitable for decoding the column address and selecting a column of the memory cell array in response to the repair determination signal.

7. The semiconductor memory device of claim 6, wherein the memory cell array includes a normal cell array and a redundancy cell array.

8. The semiconductor memory device of claim 7, wherein the column decoder selects a normal column address of the normal cell array when the column address is not the same as the repair column address, and selects a redundancy column address of the redundancy cell array when the column address is the same as the repair column address.

9. The semiconductor memory device of claim 6, wherein the repair determination unit and the column decoder are positioned in a column control region.

10. The semiconductor memory device of claim 6, wherein the fuse cell array comprises:
a plurality of fuses arranged in an array suitable for storing N number of repair column addresses, each having M bits and corresponding to a repair target memory cell; and
a fuse selection unit suitable for selecting M fuses corresponding to one of the N number of repair column addresses in the plurality of fuses in response to the row address, and outputting one of the N number of repair column addresses corresponding to the selected M fuses.

11. The semiconductor memory device of claim 10, wherein the fuse selection unit comprises:
a data sensing section suitable for sensing data stored in the selected M fuses; and
a data latch section suitable for latching the data sensed by the data sensing section.

12. The semiconductor memory device of claim 11, wherein the fuse selection unit comprises an input driving section suitable for driving one or more of word lines and program lines corresponding to the selected M fuses in response to the row address.

13. The semiconductor memory device of claim 10, wherein the row decoder comprises:
a first row decoder suitable for decoding the external row address and outputting the row address; and
a second row decoder suitable for outputting a word line select signal for selectively activating a plurality of word lines arranged in the memory cell array in response to the row address, and
wherein the fuse selection unit outputs the repair column address during an operation period of the second row decoder.

14. An operating method of a semiconductor memory device, which includes a plurality of fuses arranged in an array for storing N number of repair column addresses, each having M bits and corresponding to a repair target memory cell, the operating method comprising:
decoding an external row address applied from outside in response to an active command, and outputting a row address, which is an information of a memory cell mat corresponding to one of memory cell arrays included in the semiconductor memory device;
selectively activating a plurality of word lines arranged in each of the memory cell arrays in response to the row address;
selecting M fuses corresponding to one of the N number of repair column addresses in the plurality of fuses in response to the active command and the row address during an operation period of the activating of the plurality of word lines; and
outputting one of the N number of repair column addresses corresponding to the selected M fuses.

15. The operating method of claim 14, wherein the outputting of one of the N number of repair column addresses comprises:
sensing data stored in the selected M fuses; and
latching the sensed data.
